(19) United States
(12) Patent Application Publication
(10) Pub. No.: US 2002/0072231 A1
(43) Pub. Date: Jun. 13, 2002

(54) Method of forming a self-aligned silicide

(75) Inventors: Wei-Wu Liao, Taipei Hsien (TW); Jason J.S. Jenq, Pingtung (TW); Ching-Hsu Chan, Taipei Hsien (TW)

Correspondence Address: J. C. PATENTS, 4 Venture, Suite 250, Irvine, CA, 92618, US

(73) Assignee: United Microelectronics Corp., Hsinchu (TW)

(21) Appl. No.: 09/733,601

(22) Filed: Dec. 8, 2000

(51) Int. Cl. H01L 21/44

(52) U.S. Cl. 438/682; 438/584

(57) ABSTRACT

A method of forming self-aligned suicide. An inter-poly dielectric layer is formed on a metal-oxide semiconductor to cover a source/drain region of the metal-oxide semiconductor, while a gate thereof is exposed. A metal layer is formed to cover the exposed gate and the inter-poly dielectric layer. Performing a rapid thermal process, the metal layer is reacted with the gate to form a silicide layer. The remaining metal layer which is not reacted with the gate and the inter-poly dielectric layer are then removed to expose the source/drain region. Another metal layer is formed to cover the source/drain region. Performing a rapid thermal process, the metal layer is reacted with the source/drain region to form another silicide layer.

### BACKGROUND OF THE INVENTION

1. Field of the Invention

The invention relates in general to a method of forming self-aligned silicide (salicide). More particularly, this invention relates to a process of forming self-aligned silicide which can reduces a sheet resistance of a gate region in a MOS transistor.

2. Description of the Related Art

As the integrity of devices increases, the sheet resistance of the electrodes such as the gate and source/drain region of a metal-oxide semiconductor (MOS) transistor become equivalent to channel resistance. To adjust and reduce the sheet resistance of the gate and source/drain region, a process of self-aligned silicide is thus applied to the VLSI fabrication process of a 0.5 micron linewidth.

Typically, the self-aligned silicide process comprises forming a metal layer on a silicon surface where a silicide layer is to be formed. For example, a metal layer is often formed to cover the gate and source/drain region of a MOS device simultaneously. Performing a step of rapid thermal process (RTP), the gate and the source/drain region are reacted with this metal layer to form a silicide layer (or salicide layer) on the gate and the source/drain. The thickness of the silicide layer on both the gate and the source/drain region is therefore the same.

However, as the silidation reaction for forming such silicide layer is to react the metal layer with the silicon of the source/drain region. That is, inevitably, the silicon of the source/drain region and the gate is to be consumed. Therefore, the completeness of a shallow junction of the source/drain region may be easily damaged for consuming too much silicon. The electrical properties of the MOS device are thus seriously affected.

Therefore, a tradeoff between reduction of sheet resistance and maintenance of the completeness of the shallow junction is made in the conventional self-aligned silicide process. As the integrity keeps increasing, the linewidth of the gate shrinks further, to consider the completeness of the shallow junction frequently limits the reduction of sheet resistance of the gate, and consequently, affect the performance of the devices.

### SUMMARY OF THE INVENTION

The invention provides a method of forming self-aligned silicide. The invention forms the silicide layer on the gate and the silicide layer on the source/drain region in different stages. Therefore, the thickness of the silicide layer on the gate can be controlled, while the consumption of the source/drain region can also be adjusted to maintain the completeness of the shallow junction. As the silicide layer on the gate can be controlled with a desired thickness, so that the performance of the devices is highly enhanced.

In the invention, a semiconductor substrate comprising a gate thereon and a source/drain region therein is provided. An inter-poly dielectric layer is formed to cover the source/drain region and leave the gate exposed. A first metal layer is formed to cover the gate and the inter-poly dielectric layer. A rapid thermal process is performed, so that the first metal layer is reacted with the gate to form a first silicide layer on the gate. The remaining first metal layer which is not reacted with the gate and the inter-poly dielectric layer are removed to expose the source/drain region. A second metal layer is then formed to cover the source/drain region. A rapid thermal process is performed, so that the second metal layer is reacted with the source/drain region to form a second silicide layer on the source/drain region.

Alternatively, the second metal layer may also be formed to cover the first silicide layer formed on the gate. During the rapid thermal process, the gate can further be reacted with the second metal layer. The first silicide layer can thus be thicknened.

Both the foregoing general description and the following detailed description are exemplary and explanatory only and are not restrictive of the invention, as claimed.

### BRIEF DESCRIPTION OF THE DRAWINGS

FIGS. 1A to 1F are cross sectional views showing a method of forming self-aligned silicide according to a preferred embodiment of this invention.

### DESCRIPTION OF THE PREFERRED EMBODIMENTS

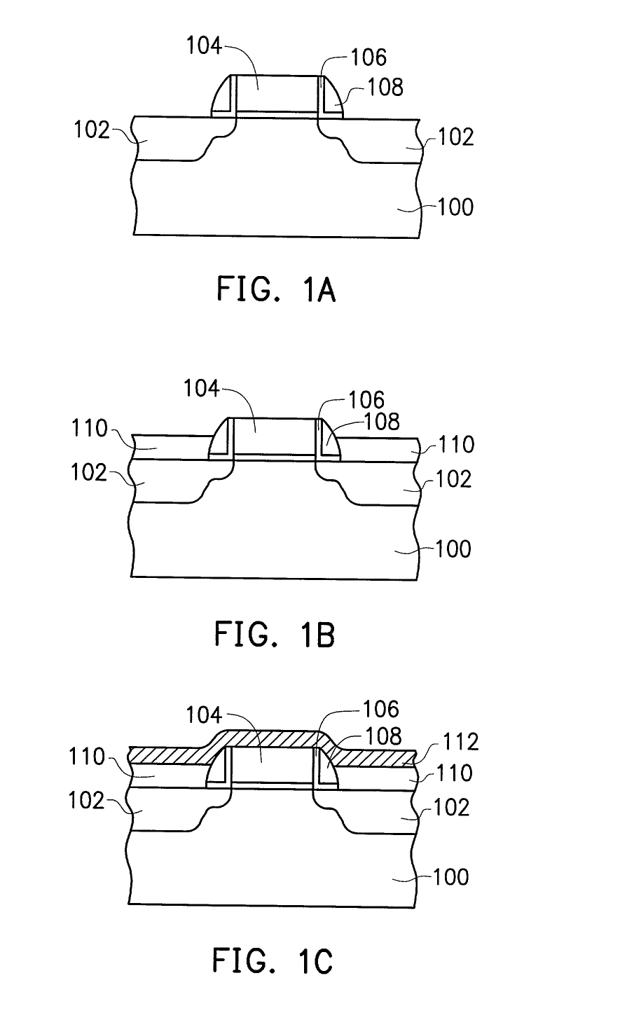

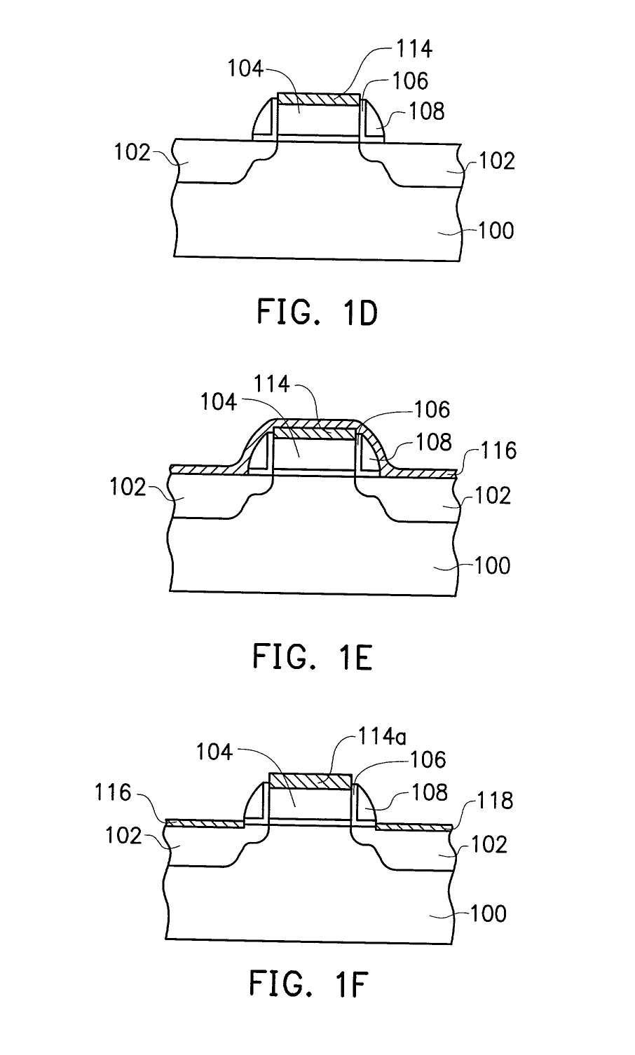

Referring to FIG. 1A to FIG. 1F, a first embodiment which provides a method of forming self-aligned silicide which can reduce a sheet resistance of gate in a MOS transistor is illustrated. In FIG. 1A, a semiconductor device, for example, a metaloxide semiconductor having a semiconductor substrate 100 such as a silicon substrate, a source/drain region 102 in the substrate 100 and a gate 104 on the substrate 100 is provided. In this embodiment, a surface of the gate 104 is covered with an oxide thin film 106, and a spacer 108, preferably formed of silicon nitride, is formed on the oxide thin film 106 on a sidewall of the gate 104.

As shown in FIG. 1B, an inter-poly dielectric layer 110, for example, an oxide or a nitride layer, is formed on the semiconductor substrate 100. The inter-poly dielectric layer 110 is etched back until the gate 104 is exposed. Meanwhile, the source/drain region 102 is still covered by the inter-poly dielectric layer 110. When a nitride layer is selected as the inter-poly dielectric layer 110, though it is not clearly illustrated in the drawing, it is inevitably that a portion of the spacer 108 is also etched away.

In FIG. 1C, a metal layer 112 is formed on the exposed gate 104 and the interpoly dielectric layer 106. The metal layer 108 comprises, for example, a refractory metal such as titanium (Ti) with a thickness of about 150-300 angstroms. The actual thickness of the metal layer 112 depends on the practical requirements. For example, the metal layer 112 can be formed by a physical vapor deposition (PVD) process such as sputtering, or a chemical vapor deposition process (CVD).

In FIG. 1D, a thermal process, preferably a rapid thermal process, is performed. The metal layer 112 is thus reacted with the underlying gate 104 to form a silicide layer 114 on the gate. As the source/drain region 102 is covered with the inter-poly dielectric layer 110, no silicide layer is formed on the source/drain region 102 so far. The resultant thickness of the silicide layer 114 depends on the thickness of the metal layer 112 and the process conditions such as the temperature and process time. Preferably, the silicide layer 114 is formed with a thickness of about 1000-2500 angstroms.

In FIG. 1E, the remaining metal layer 112 which is not reacted with the gate 104 is removed. The inter-poly dielectric layer 110 is also removed to expose the source/drain region 102.

In FIG. 1F, another metal layer 116, for example, a titanium layer formed by a physical vapor deposition process or a chemical vapor deposition, is formed to cover the source/drain region 102. The thickness of the metal layer 116 is, for example, about 150-300 angstroms. In this embodiment, the silicide layer 114 is also covered with the metal layer 112. A thermal process, preferably a rapid thermal process, is performed, so that the source/drain region 102 is reacted with the metal layer 116 to form a silicide layer 118 on the source/drain region 102. The thickness of the silicide layer 118 is dependent of the process condition and the thickness of the metal layer 116. In this embodiment, the silicide layer 118 is formed with a thickness of about 200-1000 angstroms. Meanwhile, the silicide layer 114 on the gate may also be thickened as denoted as 114a. To precisely control the thickness of the silicide layer 114 on the gate 104, one may also choose to keep the metal layer 112 away from being in direct contact with the silicide layer 114. Therefore, in the rapid thermal process to form the silicide layer 118 on the source/drain region 102, the silicide layer 114 may be maintained with a desired thickness.

As the silicide layer 114 on the gate and the silicide layer 118 on the source/drain region 102 are formed in different stages, these two silicide layers 114 and 118 can be formed with different thickness. On the other words, the silcide layer 114 (114a) on the gate 104 can be formed with a thickness as thick as required. Meanwhile, the consumption on the source/drain region can be maintained to a limit not to damage the completeness of the shallow junction with the suicide layer 118 is formed with a much smaller thickness compared to the silicide layer 114 (114a).

Other embodiments of the invention will appear to those skilled in the art from consideration of the specification and practice of the invention disclosed herein. It is intended that the specification and examples to be considered as exemplary only, with a true scope and spirit of the invention being indicated by the following claims.

What is claimed is:

1. A method of forming self-aligned silicide, comprising:
providing semiconductor substrate, the substrate comprising a gate thereon and a source/drain therein;
forming an inter-poly dielectric layer to cover the source/drain region, while the gate is exposed;
forming a first metal layer to cover the gate and the inter-poly dielectric layer;
performing a first rapid thermal process, so that the first metal layer is reacted with the gate to form a first silicide layer;
removing the metal which is not reacted with the gate and the inter-poly dielectric layer to expose the source/drain region;
forming a second metal layer on the exposed source/drain region;
performing a second rapid thermal process, so that the second metal layer is reacted with the source/drain region to form a second silicide layer; and
removing the second metal which is not reacted with the source/drain region; wherein
the first silicide layer is thicker than the second silicide layer.

2. The method according to claim 1, wherein the step of providing a semiconductor substrate comprises providing a silicon substrate.

3. The method according to claim 1, wherein the step of forming a first metal comprises forming a titanium layer.

4. The method according to claim 1, wherein the step of forming the second metal layer comprising forming a titanium layer.

5. The method according to claim 1, wherein the step of performing a first rapid thermal process comprising forming a first silicide layer with a thickness of about 1000-2500 angstroms.

6. The method according to claim 1, wherein the step of performing a second rapid thermal process comprising forming a second silicide layer with a thickness of about 200-1000 angstroms.

7. A method of forming self-aligned suicide, the method comprising:
providing a semiconductor substrate, the substrate comprising a gate thereon and a source/drain region therein;
forming an inter-poly dielectric layer to cover the source/drain region and leave the gate exposed;
forming a first metal layer on the gate and the inter-poly dielectric layer;
performing a first rapid thermal process, so that the first metal layer is reacted with gate to form a first silicide layer;
removing the remaining metal layer that is not reacted with the gate and the interpoly dielectric layer to expose the source/drain region;
forming a second metal layer on the first silicide layer and the exposed source/drain region;
performing a second rapid thermal process, so that the second metal layer is reacted with the source/drain region to form a second silicide layer, meanwhile, the first silicide layer is also thickened thereby; and
removing the remaining second metal layer which is not reacted with the source/drain region and the gate.

8. The method according to claim 7, wherein the step of performing the second rapid thermal process comprising forming a second silicide layer with a thickness of about 200-1000 angstroms and thickening a first silicide layer with a thickness of about 1000-2500 angstroms.

9. The method according to claim 1, wherein the step of forming the transparent conductive layer comprises a step of forming an indium tin oxide layer.
